(19) United States
(12) Patent Application Publication
(10) Pub. No.: US 2024/0429045 A1
(43) Pub. Date: Dec. 26, 2024

(54) ATOMIC LAYER ETCH AND SELECTIVE DEPOSITION PROCESS FOR EXTREME ULTRAVIOLET LITHOGRAPHY RESIST IMPROVEMENT

(71) Applicant: Lam Research Corporation, Fremont, CA (US)

(72) Inventors: Jengyi Yu, San Ramon, CA (US); Samantha S.H. Tan, Newark, CA (US); Liu Yang, Seattle, WA (US); Chen-Wei Liang, El Cerrito, CA (US); Boris Volosskiy, San Jose, CA (US); Richard Wise, Los Gatos, CA (US); Yang Pan, Los Altos, CA (US); Da Li, Newark, CA (US); Ge Yuan, San Jose, CA (US); Andrew Liang, San Jose, CA (US)

(21) Appl. No.: 18/757,184

(22) Filed: Jun. 27, 2024

Related U.S. Application Data
(63) Continuation of application No. 17/594,744, filed on Oct. 28, 2021, now Pat. No. 12,062,538.
(60) Provisional application No. 62/840,687, filed on Apr. 30, 2019.

(51) Int. Cl. H01L 21/02

(52) U.S. Cl. CPC H01L 21/0228; H01L 21/02164; H01L 21/02211; H01L 21/02274

(57) ABSTRACT

Provided herein are methods and systems for reducing roughness of an EUV resist and improving etched features. The methods involve descumming an EUV resist, filling divots of the EUV resist, and protecting EUV resists with a cap. The resulting EUV resist has smoother features and increased selectivity to an underlying layer, which improves the quality of etched features. Following etching of the underlying layer, the cap may be removed.

### INCORPORATION BY REFERENCE

An Application Data Sheet is filed concurrently with this specification as part of the present application. Each application that the present application claims benefit of or priority to as identified in the concurrently filed Application Data Sheet is incorporated by reference herein in its entirety and for all purposes.

### BACKGROUND

Patterning of thin films is often a critical step in the fabrication of micro- and nanoscale devices, such as in semiconductor processing for the fabrication of semiconductor devices. Patterning involves lithography. In conventional photolithography, such as 193 nm photolithography, patterns are printed by emitting photons from a photon source onto a mask and printing the pattern onto a photosensitive photoresist, thereby causing a chemical reaction in the photoresist that, after development, removes certain portions of the photoresist to form the pattern.

Advanced technology nodes (as defined by the International Technology Roadmap for Semiconductors) include nodes 22 nm, 16 nm, and beyond. In the 16 nm node, for example, the width of a typical via or line in a Damascene structure is typically no greater than about 30 nm. Scaling of features on advanced semiconductor integrated circuits (ICs) and other devices is driving lithography to improve resolution.

Extreme Ultraviolet (EUV) lithography operates on a 30 nm scale with a different light source and photoresist materials. EUV lithography can cause roughness in the photoresist due to stochastic effects. EUV lithography may also use photoresist materials that have insufficient etch selectivity to an underlying layer being etched. Both properties are undesirable.

### SUMMARY

Disclosed herein are methods and systems for reducing roughness of an EUV resist and improving etched features. This may be done by descumming, divot filling, and protecting EUV resists. The resulting EUV resist has smoother features and increased selectivity to an underlying layer, which improves the quality of etched features.

In one aspect of the embodiments presented herein, a method includes: providing to a processing chamber a semiconductor substrate including a patterned EUV resist exposing a portion of an underlying metal oxide layer; treating the exposed portion of the metal oxide layer with a halogen-containing plasma; selectively depositing a silicon-containing precursor on carbon-containing features of the patterned EUV resist; and treating the silicon-containing precursor to convert the silicon-containing precursor to a silicon oxide cap on the carbon-containing features of the patterned EUV resist. In some embodiments, treating the exposed portion of the metal oxide layer with a halogen-containing plasma is performed with a voltage bias between 0V and 100V, inclusive. In various embodiments, the halogen-containing plasma comprises a hydrogen halide. In some implementations, the halogen-containing plasma comprises HBr. In various embodiments, the silicon-containing precursor is selective to the carbon containing features compared to the metal oxide layer treated with the halogen-containing plasma at a ratio greater than about 10:1.

In some embodiments, the method further includes etching the underlying metal oxide layer using the silicon oxide cap and patterned EUV resist as a mask. In some embodiments, the silicon-containing precursor comprises one or more of SiH₄, Si₂H₂, or SiCl₄. In various embodiments, treating the silicon-containing precursor uses an oxygen-containing reactant. In some implementations, the oxygen-containing reactant is chosen from the group of H₂O, NO, N₂O, CO₂, O₂, or O₃.

In various embodiments, the method further includes, prior to treating the metal oxide layer with a halogen-containing plasma, removing non-desirable carbon material (scum) from carbon containing features of the patterned EUV resist using an atomic layer etch (ALE) process including: exposing the patterned EUV resist to a halogen-containing gas to modify the scum on a surface of the carbon-containing features; and exposing the modified scum on the surface of the patterned EUV resist to a plasma of an inert gas to remove the modified scum. In some embodiments, the halogen-containing gas comprises one or more of a halogen gas and a halide gas. In some embodiments, the halogen gas is Cl₂ or Br₂. In various embodiments, the halide gas is CF₄ or HBr. In some embodiments, the inert gas comprises helium, neon, argon, or xenon. In some embodiments, exposing the modified scum on the surface of the patterned EUV resist to a plasma is performed at a voltage bias between 0V and 100V, inclusive.

In various embodiments, the method further includes, after selectively depositing a silicon-containing precursor, modifying a surface layer of the precursor, and exposing the semiconductor substrate to a plasma of an inert gas to remove the modified layer of the precursor by atomic layer etch (ALE). In some implementations, the method further includes repeating the selective deposition and ALE operations to fill divots on carbon-containing features of the patterned EUV resist. In various embodiments, the method further includes etching the metal oxide layer using the silicon oxide cap and patterned EUV resist as a mask.

In another aspect of the embodiments disclosed herein, a method is provided that includes: providing to a processing chamber a semiconductor substrate including a patterned EUV resist exposing a portion of an underlying metal oxide layer; selectively depositing an amorphous carbon cap on carbon-containing features of the patterned EUV resist by exposing the semiconductor substrate to a gas mixture including hydrocarbon, hydrogen, and insert gas in the presence of a plasma. In some embodiments, the hydrocarbon is CH₄ or C₂H₂. In some implementations, the inert gas comprises helium, neon, argon, or xenon. In various embodiments, the method further includes, prior to selectively depositing an amorphous carbon cap, removing non-desirable carbon material (scum) from carbon containing features of the patterned EUV resist using an atomic layer etch (ALE) process including: exposing the patterned EUV resist to a halogen-containing gas to modify the scum on a surface of the carbon-containing features; and exposing the modified scum on the surface of the patterned EUV resist to a plasma of an inert gas. In some implementations, the halogen-containing gas comprises one or more of a halogen gas and a halide gas. In some embodiments, the halogen gas is Cl₂, or Br₂. In some embodiments, the halide gas is CF₄ or HBr. In some embodiments, the inert gas comprises helium, neon, argon, or xenon. In various embodiments, exposing the modified scum on the surface of the patterned EUV resist to a plasma is performed at a voltage bias between 0V and 100V, inclusive. In some embodiments, the method further includes etching the deposited amorphous carbon cap on the carbon-containing features of the patterned EUV resist. In some implementations, etching the deposited amorphous carbon cap comprises: exposing the amorphous carbon cap to an oxygen-containing reactant to modify the amorphous carbon; and

exposing the modified amorphous carbon to a plasma of an inert gas. In various embodiments, the oxygen-containing reactant is O₂, O₃, H₂O, N₂O, NO, or CO₂. In some embodiments, the method further includes repeating the selective deposition and etching the deposited amorphous carbon cap to fill divots on carbon-containing features of the patterned EUV resist. In various implementations, the method further includes etching the underlying metal oxide layer using the amorphous carbon cap and patterned EUV resist as a mask.

In another aspect of the embodiments disclosed herein, a method if provided, including: providing to a chamber a semiconductor substrate including a patterned EUV resist exposing a portion of an underlying layer; and removing non-desirable carbon material (scum) from carbon-containing features of the patterned EUV resist using an atomic layer etch (ALE) process including: exposing the patterned EUV resist to a halogen-containing gas to modify scum on a surface of the patterned EUV resist; and exposing the modified scum on the surface of the patterned EUV resist to a plasma of an inert gas. In some implementations, the underlying layer is a spin-on glass (SOG) layer or metal containing oxide. In some embodiments, the method further includes repeating in cycles: exposing the patterned EUV resist to a halogen-containing gas to modify scum on a surface of the patterned EUV resist; and exposing the modified scum on the surface of the patterned EUV resist to a plasma of an inert gas. In various embodiments, the halogen-containing gas comprises one or more of a halogen gas or a halide gas. In some embodiments, the halogen gas is Cl₂ or Br₂. In some implementations, the halide gas is CF₄ or HBr. In some embodiments, the inert gas comprises helium, neon, argon, neon, or xenon. In some embodiments, exposing the modified scum on the surface of the patterned EUV resist is performed with a voltage bias between 0V and 100V, inclusive. In various embodiments, the method further includes: selectively depositing a silicon-containing oxide precursor on the patterned EUV resist; repeating the (ALE) process including: exposing the patterned EUV resist to a halogen-containing gas to modify scum on a surface of the patterned EUV resist; and exposing the modified scum on the surface of the patterned EUV resist to a plasma of an inert gas; and treating the silicon-containing precursor to develop a silicon oxide cap on the carbon containing features of the patterned EUV resist.

In some implementations, the method further includes repeating for one or more cycles, before treating the silicon-containing oxide precursor to develop a silicon oxide cap on the carbon-containing features of the patterned EUV resist: selectively depositing a silicon-containing precursor on the patterned EUV resist; and repeating the (ALE) process including: exposing the patterned EUV resist to a halogen-containing gas to modify scum on a surface of the patterned EUV resist; and exposing the modified scum on the surface of the patterned EUV resist to a plasma of an inert gas. In various implementations, the aspect ratio between the patterned EUV resist and the exposed portions of the underlying layer is no more than 5:1. In various embodiments, the method further includes etching the underlying layer using the silicon oxide cap and patterned EUV resist as a mask.

In various embodiments, the method further includes: selectively depositing a carbon-containing material on the patterned EUV resist by exposing the semiconductor substrate to a gas mixture including hydrocarbon, hydrogen, and an insert gas in the presence of a plasma; modifying a surface layer of the selectively deposited carbon-containing material; and exposing the semiconductor substrate to a plasma of an inert gas to remove the modified surface layer by atomic layer etch (ALE). In various embodiments, the inert gas comprises helium, neon, argon, or xenon. In some embodiments, the method further includes repeating the selective deposition and ALE operations to fill divots on carbon-containing features of the patterned EUV resist. In various implementations, the method further includes exposing a substrate including a carbon-containing material to a halogen-containing gas to modify a surface of the carbon-containing material; and exposing the modified layer to an inert gas plasma for a duration sufficient to remove the modified surface.

These and other features of the disclosed embodiments will be described in detail below with reference to the associated drawings.

### BRIEF DESCRIPTION OF DRAWINGS

FIG. 1 presents a process flow diagram of operations for one example embodiment.

FIG. 2 presents an illustration of one example embodiment.

FIG. 3 presents a process flow diagram of operations for descumming.

FIGS. 4A-D presents illustrations of scum and removing scum.

FIG. 5 presents a process flow diagram of operations for another example embodiment.

FIG. 6 presents an illustration of another example embodiment.

FIG. 7 presents a process flow diagram of operations for one example embodiment.

FIG. 8 presents an illustration of another example embodiment.

FIG. 9A-C present illustrations of divot filling according to embodiments disclosed herein.

FIG. 10 is a schematic illustration of an atomic layer etch (ALE) process.

FIGS. 11 and 12 are schematic diagrams of examples of process chambers for performing methods in accordance with disclosed embodiments.

### DETAILED DESCRIPTION

In the following description, numerous specific details are set forth to provide a thorough understanding of the presented embodiments. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments.

Extreme Ultraviolet (EUV) lithography finds use in semiconductor fabrication at the 30 nm and below technology nodes. Patterned EUV resists may be used to etch a pattern into underlying layers, which requires enough thickness and/or etch selectivity of the patterned EUV resist to maintain the pattern while the layers are being etched. Increasing the thickness or etch selectivity of the patterned EUV resist can improve the transfer of the pattern to underlying layers following an etch process.

An approach to increase the thickness and etch selectivity of the patterned EUV resist is to deposit a sacrificial mask, or cap, on the patterned EUV resist. The cap may inhibit etching of the resist, thereby protecting it. Selective deposition of the cap may be performed to protect the top of the patterned EUV resist while permitting etching of exposed features, such as an underlying metal oxide layer.

Patterned EUV resists may also exhibit roughness, which may be measured by line edge roughness (LER) and line width roughness (LWR) of the resist and the resulting etch. Reducing (e.g., minimizing) roughness of the resist and the resulting etch can improve process yield and device performance at increasingly smaller critical dimensions. Reducing (e.g., minimizing) both LER and LWR can enhance the results of the EUV lithography etch process.

Incomplete removal of material following extreme ultraviolet lithographic processing of photoresists during patterning operations can increase roughness by leaving residues, referred to as “scum,” on patterned EUV resists. Scum can impact the etch of the pattern into underlying layers, which is undesirable. Scum removal, or “descumming,” without damaging other features or structures on a semiconductor substrate is desirable for patterning precision. Descumming (or “descum”) refers to a process of removing non-desirable carbon material from in between carbon-containing wafer features, such as patterned EUV resists. Thus, removal of scum can improve patterning methods and reduce roughness.

Extreme ultraviolet lithographic processing of photoresists during patterning operations can also create “divots” on patterned EUV resists, which are areas that are thinner than surrounding EUV resist. Divots may cause defects in the underlying layers by failing to mask the underlying layers during an etch process, leading to undesired etching of the underlying layer. Divot filling refers to a process of adding material to reduce variation in line thickness of wafer features, such as patterned EUV resists. Divot filling without collapsing or obscuring features or structures on a semiconductor substrate is desirable for patterning precision. Thus, filling of divots can improve patterning methods and prevent bridging defects.

In some embodiments divot filling may include cycling selective deposition and selective etch to fill divots without meaningfully increasing aspect ratio or depositing material between features. Selective deposition will only deposit on the carbon-containing features of the patterned EUV resist. Selective etch will etch inside divots at a lower rate than the non-divot areas. Thus, by repeating these two operations divots will be filled while maintaining the critical dimension of the patterned EUV resist. In some embodiments divot filling occurs as part of depositing a cap.

Provided herein are methods of depositing a cap, removing scum, and filling divots to improve patterning precision within a die, a wafer, and from lot-to-lot for EUV resists. Such techniques selectively improve etch selectivity of the patterned EUV resist and reduce roughness of etched features without modifying feature critical dimensions. Disclosed embodiments may perform one, two, or all three of depositing a cap, removing scum, and filling divots.

In various embodiments disclosed herein a semiconductor substrate is provided to a process chamber. The semiconductor substrate may be a silicon or other semiconductor wafer, e.g., a 200-mm wafer, a 300-mm wafer, or a 450-mm wafer, including wafers having one or more layers of material, such as dielectric, conducting, or semi-conducting material, deposited thereon. In some embodiments, the semiconductor substrate includes a blanket layer of silicon, such as amorphous silicon, or a blanket layer of germanium. The semiconductor substrate includes a patterned EUV resist previously deposited and patterned on the semiconductor substrate.

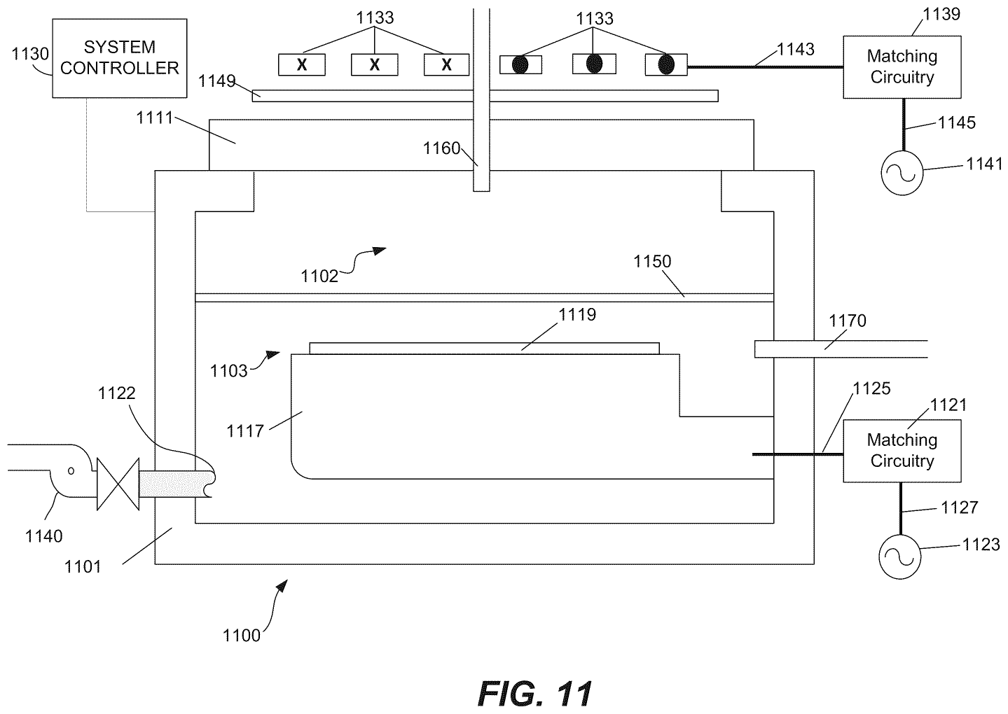

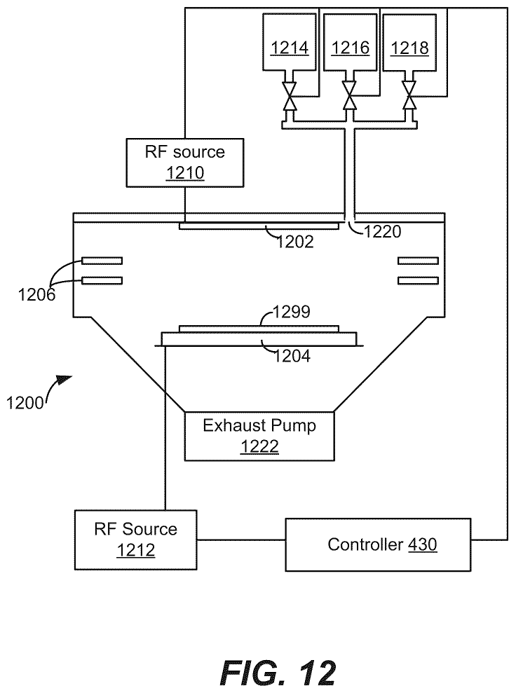

The process chamber is a semiconductor processing chamber and may be a process chamber in a multi-chamber apparatus or a single chamber apparatus, e.g. such as that shown by FIGS. 11 and 12. The semiconductor substrate may reside on a pedestal for holding the substrate.

The patterned EUV resist layer may be made of a variety of materials. In some embodiments the patterned EUV resist layer may be made of organic metal oxide-containing films, such as organotin oxides, such as are available from Inpria Corp., or traditional chemically amplified resists from Dow/Rohm, Fujifilm, JSR, TOK, and Shin-Etsu Polymer. The patterned EUV resists may also comprise chemically amplified resists. The patterned EUV resist layer may be 10-40 nm thick, for example.

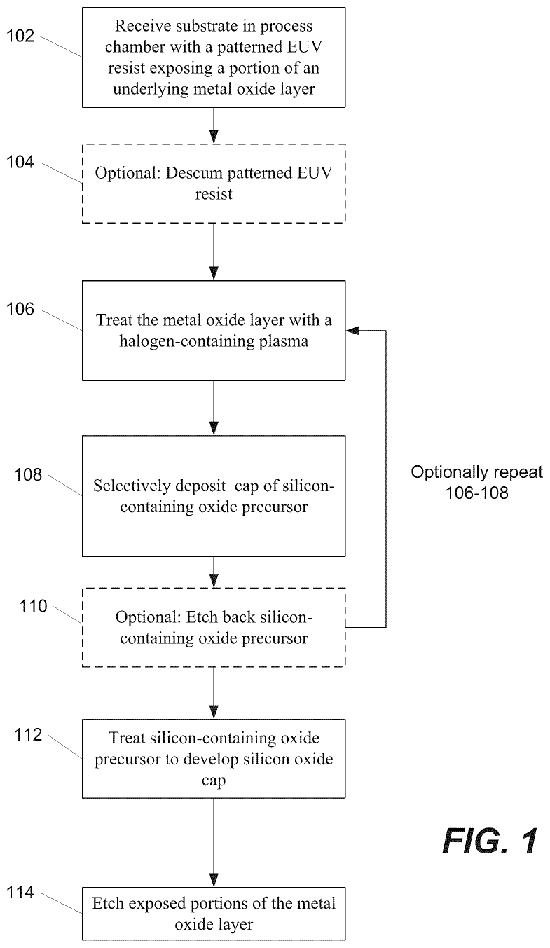

FIG. 1 provides a process flow diagram for performing operations of a method in accordance with disclosed embodiments. The method depicted in FIG. 1 may be performed as part of a process to etch a metal oxide layer. In operation 102 a semiconductor substrate (or substrate) with a patterned EUV resist exposing a portion of an underlying metal oxide layer is received in a process chamber. The semiconductor substrate may be in the process chamber from a previous operation or may be introduced to the process chamber.

Operation 104 is an optional operation to descum the patterned EUV resist. In some embodiments Operation 104 is performed to descum the patterned EUV resist, while in other embodiments operation 104 may not be performed. Whether operation 104 is performed may depend on whether any scum on the substrate impacts the critical dimension of the patterned EUV resist.

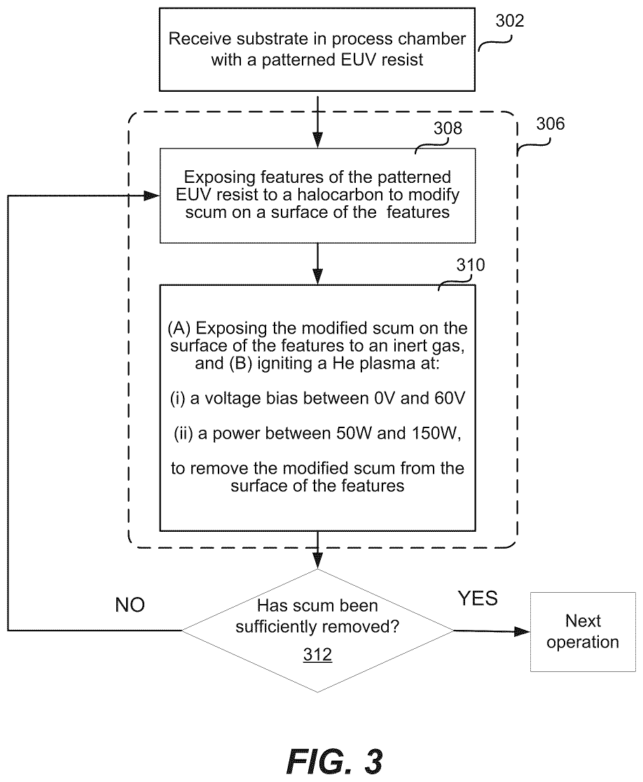

FIG. 3 provides a process flow diagram for descumming a patterned EUV resist, such as would be performed in operation 104. In operation 302 a substrate with a patterned EUV resist is received in a process chamber. The semiconductor substrate may be in the process chamber from a previous operation or may be introduced to the process chamber. The patterned EUV resist exposes portions of an underlying layer. In the context of FIG. 1, the underlying layer is a metal oxide layer. However, the method of FIG. 3 may be used with a variety of layers, including dielectric layers and conducting layers, e.g., silicon oxides, silicon nitrides, silicon carbides, metal oxides, metal nitrides, metal carbides, and metal layers.

Operation 306, which includes both operations 308 and 310, removes scum by an atomic layer etch (ALE) process. A background knowledge of ALE is helpful to explain operation 306. Generally, ALE may be performed using any suitable technique. Examples of atomic layer etch techniques are described in U.S. Pat. No. 8,883,028, issued on Nov. 11, 2014; and U.S. Pat. No. 8,808,561, issued on Aug. 19, 2014, which are herein incorporated by reference for purposes of describing example ALE and etching techniques. Examples of ALE techniques integrated with atomic layer deposition (ALD) techniques are described in U.S. Pat. No. 9,576,811, issued on Feb. 21, 2017 which is incorporated by reference herein. In various embodiments, ALE may be performed with plasma, or may be performed thermally.

ALE is performed in cycles. The concept of an “ALE cycle” is relevant to the discussion of various embodiments herein. Generally, an ALE cycle is the minimum set of operations used to perform an etch process one time, such as etching a monolayer. The result of one cycle is that at least some of a film layer on a substrate surface is etched. Typically, an ALE cycle includes a modification operation to form a reactive layer, followed by a removal operation to remove or etch only this modified layer. The cycle may include certain ancillary operations such as purging one of the reactants or byproducts.

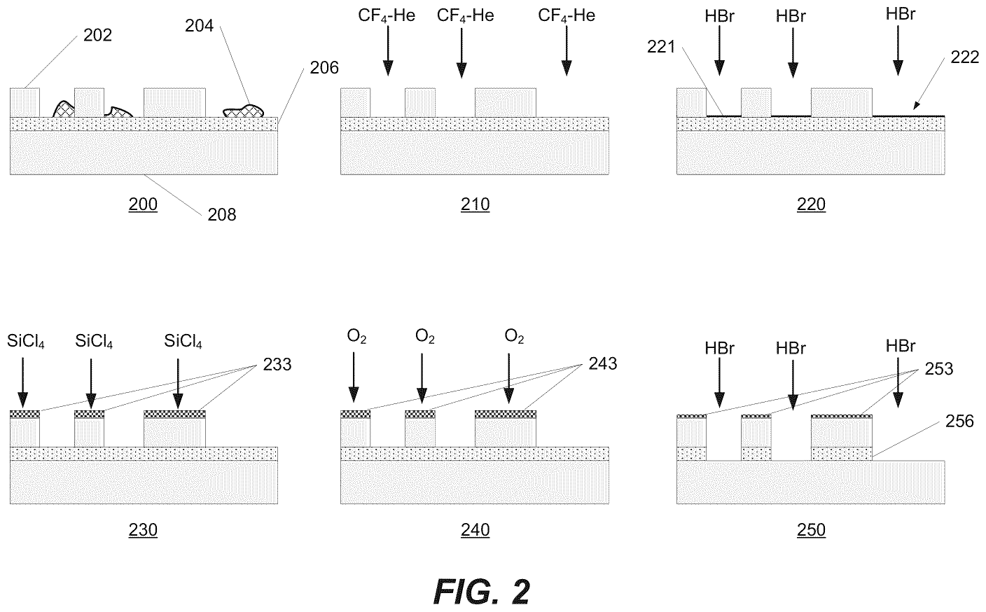

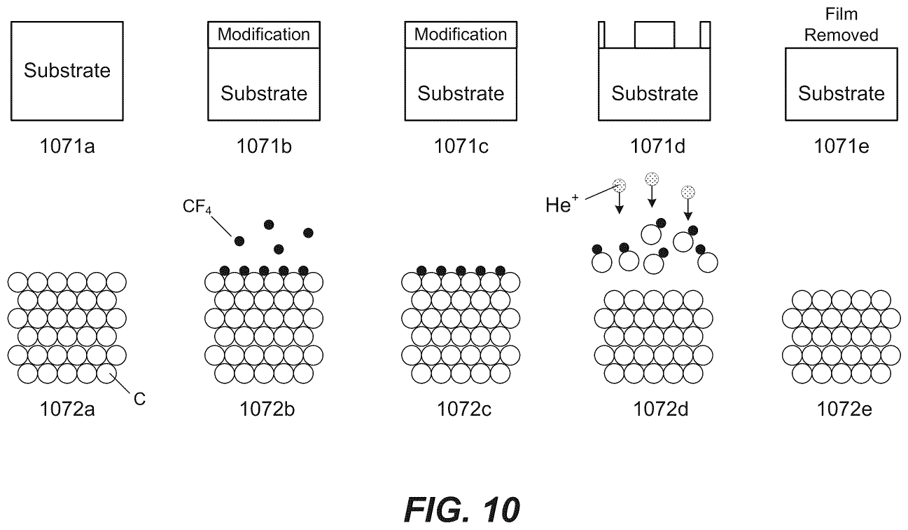

Generally, an ALE cycle contains one instance of a unique sequence of operations. As an example, an ALE cycle may include the following operations: (i) delivery of a reactant gas, (ii) purging of the reactant gas from the chamber, (iii) delivery of a removal gas and an optional plasma, and (iv) purging of the chamber. In some embodiments, etching may be performed non-conformally. FIG. 10 shows two example schematic illustrations of an ALE cycle. Diagrams 1071a-1071e show a generic ALE cycle. In 1071a, the substrate is provided. In 1071b, the surface of the substrate is modified. In 1071c, the next operation is prepared. In 1071d, the modified layer is being etched. In 1071e, the modified layer is removed. Similarly, diagrams 1072a-1072e show an example of an ALE cycle for etching a carbon containing film. In 1072a, a carbon containing substrate is provided, which includes many carbon atoms. In 1072b, reactant gas tetrafluoromethane (CF₄) is introduced to the substrate which modifies the surface of the substrate. The schematic in 1072b shows that some CF₄ is adsorbed onto the surface of the substrate as an example. Although CF₄ is depicted in FIG. 2, any halogen-containing species or suitable reactant may be used. In 1072c, the reactant gas CF₄ is purged from the chamber.

In 1072d, a removal gas helium is introduced with a directional plasma as indicated by the He+ plasma species and arrows, and ion bombardment is performed to remove the modified surface of the substrate. Although He is depicted in FIG. 2, it will be understood that other removal gases may be used, such as helium, nitrogen, argon, and combinations thereof. During removal, a bias may be applied to the substrate to attract ions toward it. For ALE, bias is often applied to the substrate to attain a desired degree of ion directionality toward the substrate. Thus, ions may be targeted to effectively remove scum from the substrate. In some embodiments, however, a bias is not used in order to reduce sputtering of the substrate and remove less material. In 1072e, the chamber is purged and the byproducts are removed.

A complete ALE cycle may only partially etch about 0.1 nm to about 50 nm of material, or between about 0.1 nm and about 5 nm of material, or between about 0.2 nm and about 50 nm of material, or between about 0.2 nm and about 5 nm of material. The amount of material etched in a cycle may depend on the purpose of the etching; for example, the amount of material etched depends on the desired critical dimension of the layer, e.g. less than 3 Å, or within a range of 2 Å to 20 Å, to be etched using patterned carbon-containing material after etching the carbon-containing material to form the pattern.

Returning to FIG. 3, in operation 308 the substrate is exposed to a halogen-containing gas, e.g., carbon tetrafluoride (CF₄), with or without igniting a plasma, to modify a surface of the carbon-containing material, e.g., on mandrels 100, on the substrate. The modification operation 308 forms a thin, reactive surface layer with a thickness, e.g., such as less than 3 Å, that is more easily removed than the un-modified material in a subsequent removal operation. Suitable halogen-containing gases include, but are not limited to: halocarbons, including fluorocarbons (CₓF_{y}), including CF₄, hydrofluorocarbons CₓH_{y}F₂), organochlorides, organobromides (CₓBr_{y}), and organoiodides (CₓI_{y}), halides, including HBr, HCl, HF, and HI, and halogen gases, including Br₂, Cl₂, F₂, and I₂. In some embodiments the halogen-containing gas is Br₂ or Cl₂. In some embodiments the halogen-containing gas is CF₄ or HBr. Halogen dosing of the substrate generates a saturated monolayer or sub-monolayer on the substrate. Halogens may be adsorbed onto the surface of the substrate without reacting with the carbon-containing material. Halogen-containing gases may be optionally accompanied by a carrier gas which may be any of helium, nitrogen, argon, neon, xenon, and combinations thereof. Operation 308 may be performed for a duration sufficient to obtain complete saturation of the substrate surface with the halogen-containing gas. In some embodiments, the duration may be about 0.1 second. In some embodiments, the duration may be between about 0.1 seconds and about 3 seconds, such as about 0.5 seconds, or about 1 second. For example, in some embodiments, the chamber pressure may be about 5 mTorr to 100 mTorr, chamber temperature less than 60° C., plasma power per substrate station between about 50 W and about 150 W, and voltage bias between 0V and 60V. The reactant flow may be between 100 sccm-300 sccm. All process conditions ranges are inclusive.

In operation 310, the substrate, including the saturated monolayer, is exposed to an inert gas and a plasma is ignited to remove the modified surface. The plasma applied in operation 310 may be a helium-containing, or helium-derived plasma with a frequency of 13.56 MHz or 27 MHz. Plasmas derived, or generated, from N₂ may also be employed. The selection of a plasma may be determined on the number of ligands, or co-ligands, associated with a plasma generated from a given gas. For instance, lower amounts of ligands, or co-ligands, tend to result in the plasma demonstrating relatively directional behavior. However, lower amounts of ligands, or co-ligands, may result in relatively energized ions, e.g. of the plasma, which thus etch more.

In some embodiments, frequencies of 400 kHz and 60 MHz may be employed to control ion energy. Also, optionally, pulsed plasma activation techniques and dual-frequency activation, e.g. tandem low and high frequency, may be employed. Plasma sources may include capacitively-coupled reactors (CCPs) or inductively coupled reactors (ICPs) as delivered from a SHD, or are thermal-based, ultraviolet-based, or photon-based.

The inert gas may be selected from a group including, but not limited to, Ar, He, N₂, or the substrate may be alternatively exposed to a vacuum. To remove scum modified upon exposure to a halogen-containing gas as shown in operation 308, the surface of the features and the substrate may be exposed to an energy source at operation 310. Suitable energy sources may include activating or sputtering gases or chemically reactive species that induce removal, such as helium, to etch (or descum) the substrate by directional sputtering. In some embodiments, the removal operation may be performed by ion-bombardment. In some embodiments operations 302-312 are performed with a voltage bias to modulate the directionality of etching to achieve a desired profile. In some embodiments operations 302-312 are performed without a voltage bias to isotropically remove scum from the surface of the features.

The amount of sputtering gas may be controlled to etch (or descum) only a targeted amount of material, such as less than 3 Å, or within a specified range of 2 Å to 20 Å. For example, sputtering gases such as helium or argon may be flowed to a process chamber at 100-300 sccm. Further, the etch (or descum) profile of the substrate may be controlled by modifying the ratio of helium to argon. Generally, greater helium content will etch less and reduce sputtering, while greater Argon content will etch more and increase sputtering. In some embodiments, the pressure of the chamber may vary between modification and removal operations. The pressure of the gas may depend on the size of the chamber, the flow rate of the gas, the temperature of the reactor, the type of substrate, and the size of substrate to be etched. In some embodiments, higher pressure of the gas may allow for relatively faster cycle completion times. In some embodiments the chamber pressure is between 5 mTorr and 100 mTorr.

Plasma is ignited at a plasma power selected to reduce sputtering of the material on the substrate surface while controlling the amount of material etched in each cycle. In some embodiments, the plasma power for a single substrate station may be between about 50 W and about 150 W, e.g. 100 W. Although the use of plasma may cause some sputtering in general, sputtering may be generally controlled by performing disclosed embodiments at a low plasma power and low voltage bias, or pulsing the voltage bias, to obtain fine-tuned control over the amount of material etched per cycle and to thereby pattern carbon-containing material to obtain vertical, or clean, feature sidewalls. For example, in some embodiments, the chamber pressure may be about 5 mTorr to 100 mTorr, plasma power per substrate station between about 50 W and about 150 W, and voltage bias between 0V and 100V. In some embodiments, the voltage bias may be pulsed between 0V and about 400V, or 0V and about 100V. In some embodiments, the plasma may be ignited for a duration of less than about 5 seconds, such as between about 1 second and about 5 seconds. All process conditions are inclusive.

In operation 312, it is determined whether the substrate has been sufficiently etched or cleaned. If not, operations 308-312 may be optionally repeated. Performing operation 306 may constitute one ALE cycle. In various embodiments, etching, or descumming, may be performed in cycles. The number of cycles depends on the amount of etching desired for the particular application. In various embodiments, between about 1 cycle and about 100 cycles may be used. In some embodiments, about 5 cycles to about 100 cycles may be used. In some embodiments the number of cycles may be about 1 to about 40 cycles, or about 1 to about 20 cycles, or about 30 to about 40 cycles. Any suitable number of ALE cycles may be included to etch a desired amount of film. In some embodiments, ALE is performed in cycles to etch about 1 Å to about 50 Å of the surface of the layers on the substrate. In some embodiments, cycles of ALE etch between about 2 Å and about 50 Å of the surface of the layers on the substrate. In some embodiments, the number of cycles may be selected by using optical emission spectroscopy (OES) to identify the amount of etch and set an endpoint to stop etching at the endpoint. In some embodiments, the cycle time (duration for a single cycle) may be less than 1 second. ALE, as presented and discussed in FIGS. 3, may be conducted at an etch rate of 0.5 Å to 3 Å per cycle. Many ALE processes more typically remove from about 4 Å to 10 Å per cycle.

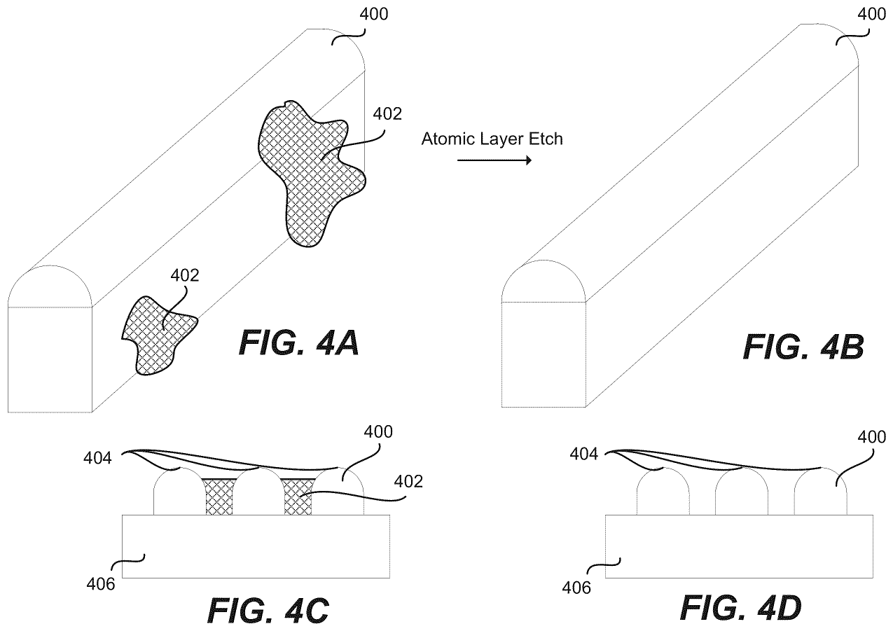

FIGS. 4A-D show a perspective and side view of a patterned EUV resist that has been descummed by the process of FIG. 3. FIG. 4A shows a perspective view of a patterned EUV resist having features, e.g., mandrel 400, with photoresist (PR) scum 402 on, or extending from, the mandrel 400. The scum 402 is removed by an atomic layer etch (ALE) process from the mandrel 400, as shown in FIG. 4B. FIGS. 4C and 4D show cross-sectional side views of an array 404 of mandrels 400 formed on a substrate 406. One of ordinary skill in the art will appreciate the substrate 406 may comprise a multi-layer stack suitable for semiconductor processing which may also include other layers, such as etch stop layers, cap layers, barrier layers, and other under-layers.

Non-desired carbon-based material, such as footings, stringers, or other forms of undesirable substrate surface roughness remaining on a substrate after lithography are collectively referred to herein as “scum,” e.g., scum 402. In some embodiments, scum 402 may contain carbon at a level similar, or identical to, the mandrel 400, also referred to as a carbon-containing feature. As shown in FIG. 4C, several mandrels 400 may be oriented adjacent to one another in an array 404. Scum 402 may pose a patterning risk by remaining on substrate 406 after lithography to connect the mandrels 400, e.g. when organized, or positioned, in the array 404. Such a connection of the mandrels 400 by the scum 402 is undesirable, thus scum 402 is cleaned by an ALE process, for example as shown and described with reference to FIGS. 3, leaving array 404 of mandrels 400 free from scum 402, as shown in FIG. 4D.

In some embodiments, scum 402 is a residue of the EUV resist development process that is relatively dispersed across the mandrel 400, as shown in FIG. 4A, and thus forms a thin layer on the mandrel. Such scum 402 thus has a relatively high surface area to volume ratio, and thus may be more susceptible to removal by an ALE process. Also, in some embodiments, scum 402 may be integrated with, or into, the mandrel 400, being formed of generally the same material as the scum 402. Thus, scum 402 may be thought to be an undesirable protrusion of the mandrel 400.

Returning to FIG. 1, following the optional descumming of the patterned EUV resist in operation 104, in operation 106 the substrate is exposed to a halogen-containing plasma to treat the exposed portions of the metal oxide layer. Suitable halogen-containing plasmas include hydrogen halides (HF, HCl, HBr, or HI) and diatomic halogens (Br₂, Cl₂, F₂, I₂). The halogen-containing plasma is a ‘gentle’ plasma, in that a sufficiently low power and low bias are used to form a halide layer on the metal oxide layer, and to not etch or nominally etch the metal oxide layer. In some embodiments a gentle plasma has a power for a single station between 10 W and 150 W, e.g. 100 W, and a voltage bias between 0V and 60V, e.g. 0V. In some embodiments the chamber pressure is between 10 mTorr and 100 mTorr, and the chamber temperature is less than 60° C., e.g. 20° C. In some embodiments the flow rate of halogen-containing gas is between 100 sccm and 300 sccm, e.g. 100 sccm. In some embodiments the exposure time, or the time that halogen-containing gas is flowing into the chamber, is between 30 s and 90 s, e.g. 60 seconds.

Halide layers can inhibit deposition on the metal oxide layer by increasing the nucleation delay for later deposition operations. When performed with a low power and bias, a halide layer will form on the exposed portions of the metal oxide layer, including open areas of the exposed portions, or areas that have a low aspect ratio to features of the patterned EUV resist, such as an aspect ratio below about 1. The halide layer inhibits the deposition of certain reactants, specifically silicon-containing precursors, by increasing the nucleation delay for such reactants.

In operation 108 a precursor layer of silicon-containing oxide precursor is deposited on the patterned EUV resist. The precursor is generally deposited “selectively” with respect with respect to the top of the features of the patterned EUV resist, such that more precursor deposits on top of the features than sidewalls or the exposed portions of the metal oxide layer. For example, in some embodiments there is no sidewall deposition of precursor. The halide layer inhibits deposition of the precursor such that the precursor does not deposit on the metal oxide layer. This inhibition, or nucleation delay time, may last for between 1 second and 6 seconds, or about 3 seconds, after which the silicon-containing precursor may also deposit on the halide layer or the exposed portions of the metal oxide layer. In some embodiments the silicon-containing precursor is SiH₄, Si₂H₂, or SiCl₄.

Example process conditions for depositing silicon-containing precursor are power between 100 W-500 W, e.g. 300 W, 50V-200V bias, e.g. 120V, chamber temperature below 60° C., chamber pressure between 5 mTorr and 100 mTorr, e.g. 50 mTorr, and exposure time between 1 s and 5 s. Reactant flow is between 10 sccm-50 sccm SiCl₄, 0 sccm-200 sccm H₂, and 100 sccm-300 sccm He. All process condition ranges are inclusive.

Operation 110 is an optional operation to etch back the precursor layer. In some embodiments the precursor layer is deposited for a sufficient time that it forms on the halide layer or the exposed portions of the metal oxide layer. Operation 110 may then be performed to remove such undesirable deposition, such that the net effect of operations 108 and 110 is the deposition of a precursor layer on only the patterned EUV resist, and no deposition on the halide layer or the metal oxide layer. In some embodiments operation 110 may also remove the halide layer, such that the exposed portions of the metal oxide layer no longer exhibit a nucleation delay time for deposition of silicon-containing precursors. In some embodiments, the deposition time of the precursor layer is insufficient to overcome the nucleation delay caused by the halide layer, and the precursor layer does not form on the halide layer or metal oxide layer. In such embodiments operation 110 may not be performed as the precursor layer has not deposited on the halide layer or metal oxide layer. Operation 110 may be performed according to the process flow diagram of FIG. 3 as described above.

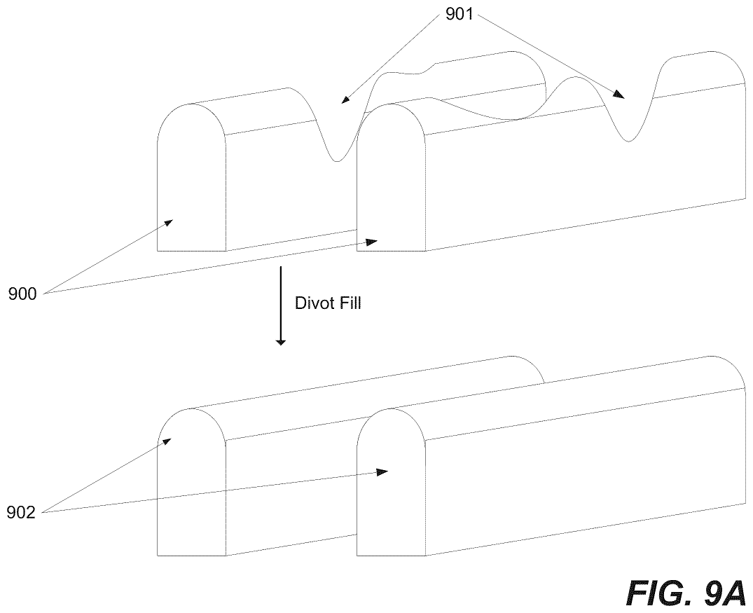

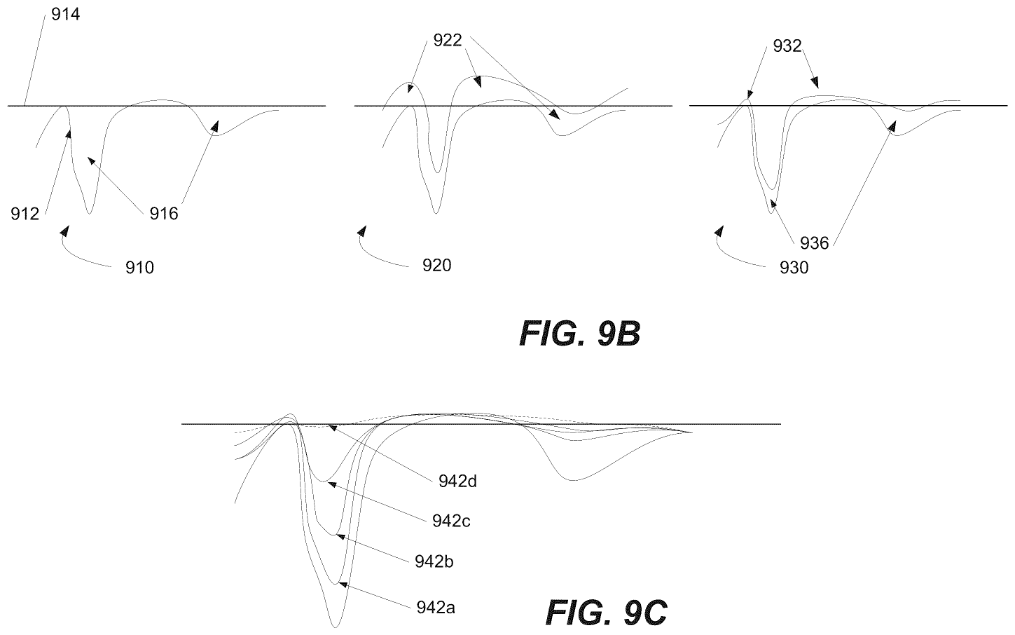

In some embodiments, operations 106-110 are cycled to fill divots in the patterned EUV resist. FIG. 9A-C show a perspective and side view of a patterned EUV resist that has had divots filled by cycled deposition and etch operations. FIG. 9A shows a perspective view of a patterned EUV resist having features, e.g. mandrels 900, with divots 901 in the mandrel 900. The divots 901 are filled by cycling deposition and etch operations, as shown in FIGS. 9B and 9C, to form mandrels 902. One of ordinary skill in the art will appreciate the mandrels 900 and 901 may comprise a multi-layer stack suitable for semiconductor processing, which may also include other layers, such as etch stop layers, cap layers, barrier layers, and other under layers.

FIG. 9B shows a side view of a mandrel during a single cycle of divot filling. In operation 910 a substrate with a patterned EUV resist 912 having divots 916 is received in a process chamber. The substrate may be in the process chamber from a previous operation or may be introduced to the process chamber. Line 914 is an imaginary line representing an ideal thickness for the EUV resist.

In operation 920 a deposition layer 922 is selectively deposited on the patterned EUV resist 912. In some embodiments more material will deposit in the divots 916 than surrounding areas of the patterned EUV resist 912. The deposition is selective to the patterned EUV resist compared to exposed portions of a layer underlying the patterned EUV resist. Process conditions for the deposition process may include any deposition process conditions discussed herein for depositing a precursor or cap layer of material.

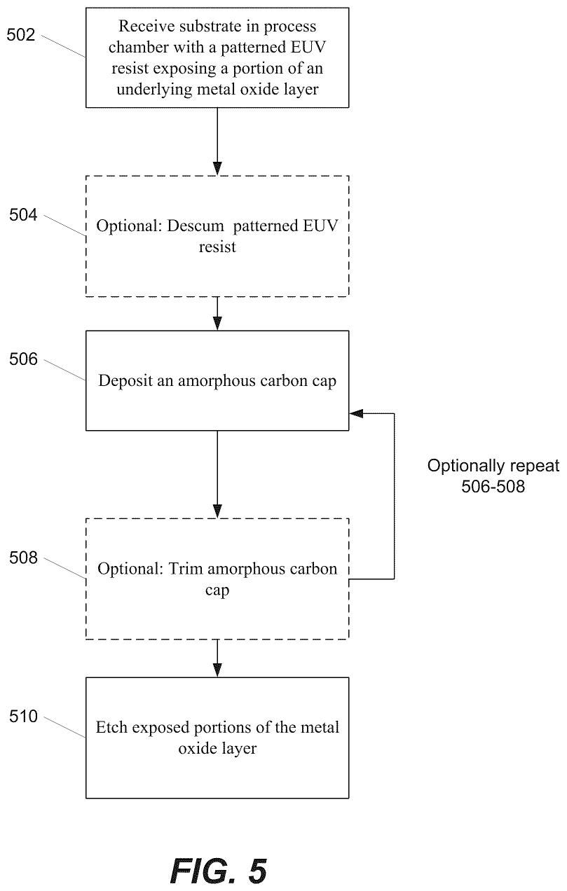

In operation 930 the substrate is etched, forming filled divots 936 and capped EUV resist 932. Filled divots 936 are smaller than divots 916, while the capped EUV resist 932 has a similar thickness as patterned EUV resist 912. The etch process of operation 930 is selective, in that material inside of divots is etched less than material outside of divots, causing a net fill of the divots while maintaining the thickness of the EUV resist. Process conditions for the etch process depend on the deposited material, and generally material within a divot is etched less, or at a lower rate, than material in the area surrounding the divot. In some embodiments operation 930 may be accomplished by an aspect ratio dependent etch or a surface area dependent etch. In some embodiments operation 930 may be performed according to the process flow diagram of FIG. 3 as describe above. In other embodiments operation 930 may be performed according to operation 508 of FIG. 5, as described below.

FIG. 9C is a side view of a patterned EUV resist after completing four cycles of divot filling. Side profiles 942a-d show the fill of divots after successive cycles of deposition and etch, as shown in FIG. 9B. The resulting EUV profile 942d is substantially similar to the line 914 that represents an ideal thickness for the EUV resist.

Returning to FIG. 1, operations 106-110 may be cycled to fill divots of the patterned EUV resist. Operation 106 may be performed to form a halide layer on the exposed portions of the metal oxide layer. Operation 108 may be performed to deposit a silicon-containing oxide precursor on the patterned EUV resist, including inside of divots, without depositing or with less deposition on the halide layer or exposed portions of the metal oxide layer. Operation 110 may then be performed to etch the silicon-containing oxide precursor, and in some embodiments the halide layer on the exposed portions of the metal oxide layer. Thus, each cycle of operations 106-110 will result in a greater deposition inside of divots than the surrounding area. Operations 106-110 may be cycled until the patterned EUV resist has substantially no divots.

In some embodiments only operations 108 and 110 are cycled. Since the halide layer reacts with the silicon-containing precursor in operation 110, it may continue to inhibit deposition of the silicon-containing precursor in operation 108 by increasing the nucleation delay time if it has not completely reacted with the silicon-containing precursor. In such embodiments operation 106 is unnecessary to increase the selectivity of the deposition in operation 108.

In operation 112 the precursor layer of silicon-containing oxide precursor is oxidized to form a silicon oxide cap. This is done by exposing the substrate to an oxidant, i.e. an oxygen-containing gas, while igniting a plasma, which reacts with the silicon-containing oxide precursor to form a silicon oxide cap on the patterned EUV resist. The silicon oxide cap is selectively formed on top of the features of the patterned EUV resist, rather than the sidewalls, maintaining the sidewall profile of the features. Suitable oxidants include, but are not limited to: nitrous oxide (N₂O) gas, diols, water, oxygen, ozone, alcohols, esters, ketones, carboxylic acids, and mixtures thereof. Example process conditions for oxidizing the silicon-containing oxide precursor are 10 W-150 W, e.g. 100 W, 0V bias, process chamber temperature below 60° C., pressure between 5 mTorr and 100 mTorr, e.g. 5 mTorr, and exposure time between 5 s and 15 s, e.g. 5 s. Reactant flow may be between 100 sccm-300 sccm O₂. All process condition ranges are inclusive.

In operation 114 the metal oxide layer is etched, using the patterned EUV resist and the silicon oxide cap as a mask. The substrate is exposed to etching gases and a directional plasma that is selective to the metal oxide layer, i.e. the metal oxide layer is etched at a higher rate than the EUV resist or silicon oxide cap. The silicon oxide cap protects the patterned EUV resist from the etchant gas, preventing or inhibiting etching of the patterned EUV resist until the silicon oxide cap has been etched. In some embodiments the silicon oxide cap is completely removed during etching of the metal oxide layer, while in other embodiments the silicon oxide cap is not removed. Potential etching gases include halogen-containing gases. The etch selectivity for the metal oxide layer compared to the silicon oxide cap may be from about 10:1-15:1. Example process conditions for etching the metal oxide layer are power between 100 W-500 W, e.g. 300 W, 100V-300V bias, chamber temperature below 60° C., chamber pressure between 10 mTorr and 100 mTorr, e.g. 20 mTorr, and exposure time between 10 s and 30 s. Reactant flow may be between 100 sccm-300 sccm HBr and between 100 sccm-300 sccm He. All process condition ranges are inclusive.

A particular example of the method of FIG. 1 is discussed below with reference to FIG. 2. FIG. 2 presents an example embodiment of a side view of a semiconductor substrate during deposition of a cap on a patterned EUV resist during an etch process. At operation 200 a semiconductor substrate 208 having a metal oxide layer 206, carbon-containing scum 204, and patterned EUV resist features 202 is provided to a processing chamber.

At operation 210 the substrate is descummed by an ALE process using CF₄ to adsorb onto surfaces of the substrate, and He ions to sputter the adsorbed layer. Operation 210 may be repeated until scum 204 is sufficiently removed, performing multiple ALE cycles. The result of operation 210 is the removal of scum 204. In some embodiments operation 210 also etches the features 202 and the metal oxide layer 206, but to a much lesser extent than the scum is etched for removal.

In some embodiments, operation 210 is not performed. In some embodiments scum 204 may be insignificant enough such that a descum operation is unnecessary. In some embodiments the EUV lithography process may not create sufficient scum to warrant a descum operation. Generally, if the scum does not impact the critical dimension of the etch process, a descum operation may not be performed.

In operation 220 the exposed portions of the metal oxide layer are treated with an HBr plasma to develop a passivation layer 221. The passivation layer also forms on the open area 222, where there is a lower aspect ratio between the width of the exposed area and the height of features 202. The HBr treatment passivates the metal oxide layer, inhibiting deposition of silicon-containing precursors, such as silicon tetrachloride (SiCl₄).

In operation 230 a silicon-containing precursor, such as SiCl₄, is selectively deposited on top of features 202 to create a silicon-containing precursor layer 233. SiCl₄ does not deposit on the metal oxide layer 206 due to the nucleation delay time caused by passivation layer 221. SiCl₄ also does not substantially deposit on the sidewalls of the features.

In some embodiments the deposition time of SiCl₄ is sufficiently long such that a layer of SiCl₄ forms on the passivation layer as well. This undesired deposition may be removed prior to oxidizing the deposited SiCl₄ to create silicon oxide by performing an etch back operation according to the process flow diagram described in FIG. 3 above. In some embodiments operation 220, 230, and the etch back operation may be cycled to fill divots. In other embodiments only operation 230 and the etch back operation are cycled to fill divots.

In operation 240 the silicon-containing precursor layer 233 is exposed to an oxygen plasma to create a silicon oxide (SiO₂) cap 243. The oxygen reacts with the silicon-containing precursor layer to form an oxide. The silicon-containing precursor layer is exposed to oxygen for a variable amount of time, depending on the thickness of the silicon-containing precursor layer, to ensure it completely oxidizes.

Finally, in operation 250 the metal oxide layer is etched using an HBr plasma. Unlike the HBr plasma used in operation 220, this plasma is created with a higher energy and with a higher voltage bias in order to etch the metal oxide layer, rather than deposit a layer of HBr thereon. As the exposed portions of the metal oxide layer 206 are etched by the HBr plasma, a patterned metal oxide layer 256 is formed. Patterned metal oxide layer 256 has the same patterning as features 202 of the patterned EUV resist. The silicon oxide cap 243 is also etched to a thinner cap 253, but etches at a much lower rate than the metal oxide layer. In some embodiments the silicon oxide cap will be removed in operation 250 by the etch process.

FIG. 5 provides another process flow diagram for performing operations of a method in accordance with disclosed embodiments. The method in FIG. 5 may be performed as part of another process to etch a metal oxide layer. In operation 502 a substrate with a patterned EUV resist exposing a portion of an underlying metal oxide layer is received in a process chamber. The semiconductor substrate may be in the process chamber from a previous operation or may be introduced to the process chamber.

Operation 504 is an optional operation to descum the patterned EUV resist. In some embodiments Operation 504 is performed to descum the patterned EUV resist, while in other embodiments operation 504 is not performed. Whether operation 504 is performed may depend on whether any scum on the substrate impacts the critical dimension of the patterned EUV resist. Operation 504 may be performed according to the process flow diagram of FIG. 3 as described above.

In operation 506 an amorphous carbon cap is deposited on the patterned EUV resist. A voltage bias may be applied to increase the conformality of the carbon-based deposition, though in some embodiments there will be deposition on the sidewalls of features of the patterned EUV resist. The amorphous carbon deposition may be conducted by exposing the substrate to a hydrocarbon (CₓH_{y}), such as methane (CH₄), a hydrogen (H₂) in the presence of a plasma to deposit on the features of the patterned EUV resist. H ions typically etch metal oxide layers, while carbon-based polymers, such as an EUV resist, are resistant to H ion etching. Additionally, carbon radicals in plasma will deposit on carbon-based polymers, such as an EUV resist. Thus, the hydrocarbon and H₂ plasma can be tuned to deposit amorphous carbon on the patterned EUV resist, while not depositing on, or nominally etching, the exposed portions of the underlying metal oxide layer.

Example process conditions for some embodiments include: single station power between 10 W-200 W, e.g. 100 W, voltage bias between 0V-100V, e.g. 60V, process chamber temperature less than 60° C., pressure between 1 mtorr-100 mtorr, and exposure time between 1 s-10 s. In some embodiments the reactants are CH₄, with a flow rate between 10 sccm-50 sccm, e.g. 20 sccm, H₂, with a flow rate between 0 sccm-200 sccm, e.g. 50 sccm, and an inert gas, such as helium, with a flow rate between 200 sccm-400 sccm, e.g. 250 sccm, though other inert gases may be used. All process condition ranges are inclusive.

In some embodiments an optional operation 508 is performed to reduce or remove carbon deposited in operation 506 from the sidewalls of features of the patterned EUV resist. Operation 508 etches the substrate, removing carbon from the top and sidewalls of the patterned EUV resist. The amorphous carbon deposits more on the top of the features than the sidewalls, and thus operation 508 results in a net deposition of amorphous carbon on top of the features of the patterned EUV resist. This may be done to reduce LER or LWR or maintain feature critical dimensions. In some embodiments this operation is not performed, as any sidewall deposition is insufficient to impact feature critical dimensions.

The etch back operation 508 may proceed in an ALE manner, using the same process conditions as the descum operation discussed above with respect to FIGS. 3 and 10. In some embodiments the reactants of the descum operation (e.g., CF₄) are used for the etch back operation. In other embodiments, instead of a halogen-containing gas, an oxidant is adsorbed onto the surface of the carbon-containing features, which is then removed by a helium plasma. Suitable oxidants include, but are not limited to: oxygen, ozone, water, carbon dioxide (CO₂), nitrous oxide (N₂O) gas, diols, alcohols, esters, ketones, and carboxylic acids.

In some embodiments operation 506 and 508 are cycled to fill divots in the patterned EUV resist. In some embodiments operation 506 will selectively deposit within divots, i.e. more carbon will deposit within divots than areas surrounding the divots. In some embodiments operation 508 will etch within divots less than the surrounding, thicker area. By cycling operations 506 and 508, any divots may be gradually filled by the amorphous carbon precursor layer, reducing variability in the EUV resist thickness.

Finally, in operation 510 the metal oxide layer is etched, using the patterned EUV resist and the amorphous carbon cap as a mask. The amorphous carbon cap protects the patterned EUV resist from the etchant gas, preventing or inhibiting etching of the patterned EUV resist until the amorphous carbon cap has been removed. In some embodiments the amorphous carbon cap is completely removed during etching of the metal oxide layer, while in other embodiments the amorphous carbon cap is not removed. The etch selectivity for the metal oxide layer compared to the amorphous carbon cap may be from about 10:1-15:1. Example process conditions for operation 510 are the same as for operation 114 in FIG. 1, above.

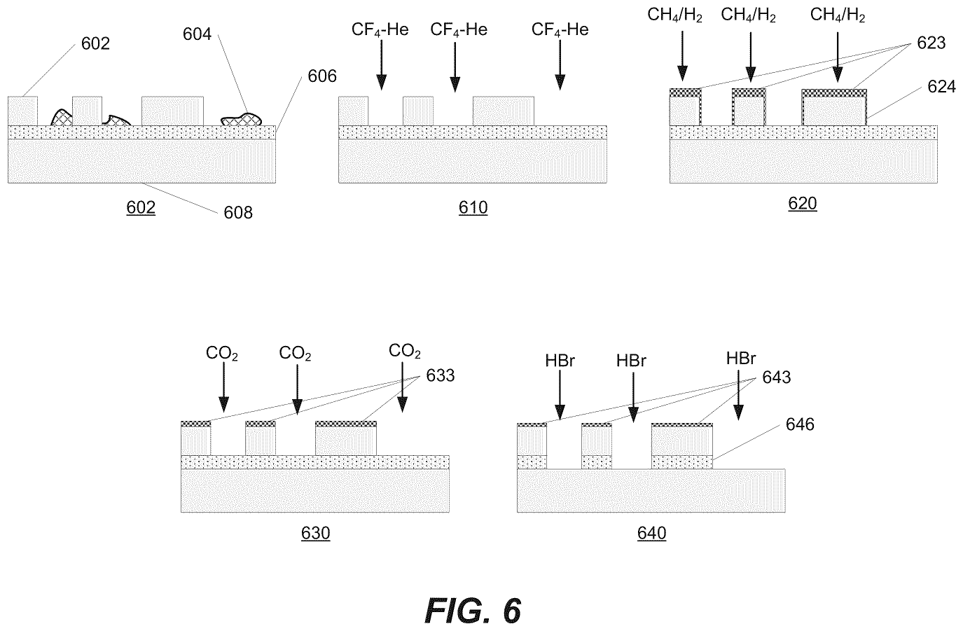

A particular example of the method of FIG. 5 is discussed below with reference to FIG. 6. FIG. 6 presents an example embodiment of a side view of a semiconductor substrate during deposition of a cap on a patterned EUV resist during an etch process. At operation 600 a semiconductor substrate 608 having a metal oxide layer 606, carbon-containing scum 604, and patterned EUV resist features 602 is provided to a processing chamber.

At operation 610 the substrate is descummed by an ALE process using CF₄ to adsorb onto surfaces of the substrate, and He ions to sputter the adsorbed layer. Operation 610 may be repeated until scum 604 is sufficiently removed, performing multiple ALE cycles. The result of operation 610 is the removal of scum 604. In some embodiments operation 610 also etches the features 602 and the metal oxide layer 606.

In some embodiments, operation 610 is not performed. In some embodiments scum 604 may be insignificant enough such that a descum operation is unnecessary. In some embodiments the EUV lithography process may not create sufficient scum to warrant a descum operation. Generally, if the scum does not impact the defect performance or critical dimension of the etch process, a descum operation may not be performed.

In operation 620 the substrate is exposed to a methane and hydrogen plasma to selectively deposit amorphous carbon on top of features 602 to form an amorphous carbon layer 623. As discussed above, the process conditions are tuned so that the carbon plasma will deposit on the features 602, while the hydrogen plasma will remove any amorphous carbon deposition on the metal oxide layer and may nominally etch the metal oxide layer. In some embodiments amorphous carbon may deposit on the sidewalls of the features 602 to form sidewall carbon 624. The carbon is deposited using a voltage bias to increase the anisotropy of the deposition, but some sidewall deposition may invariably occur.

In operation 630 the amorphous carbon precursor layer 623 and sidewall carbon 624 is etched back by an ALE process using carbon dioxide (CO₂) to adsorb onto carbon-containing surfaces of the substrate, then He ions to desorb the adsorbed layer and form an amorphous carbon cap 633. This operation is used to remove any carbon that deposited on the sidewalls, but also removes carbon on top of features 602. Because the carbon was selectively deposited in operation 620 such that more carbon deposited on top than on the sidewalls, the amorphous carbon cap 633 will still remain after operation 630.

In some embodiments operation 630 is not performed. In some embodiments the sidewall carbon 624 does not impact the critical dimension of the features to be etched, and this operation may be skipped in order to increase throughput. In such embodiments the carbon layer 623 is the amorphous carbon cap used in operation 640.

Finally, in operation 640 the metal oxide layer is etched using an HBr plasma. The HBr plasma is created with a high energy, and a voltage bias is applied to the semiconductor substrate, in order to etch the metal oxide layer, rather than deposit a layer of HBr thereon. As the exposed portions of the metal oxide layer 606 are etched by the HBr plasma, a patterned metal oxide layer 646 is formed. Patterned metal oxide layer 646 has the same patterning as features 602 of the patterned EUV resist. The amorphous carbon cap 633 (or amorphous carbon precursor layer 623) is also etched to a thinner cap 643, but etches at a lower rate than the metal oxide layer. In some embodiments the amorphous carbon cap is removed during operation 640 by the etch process.

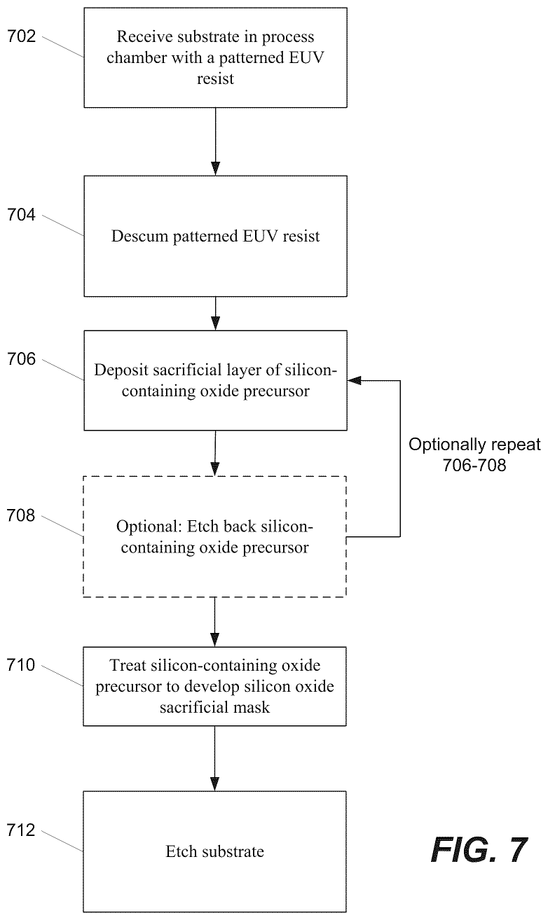

FIG. 7 provides a process flow diagram for performing operations of another method in accordance with disclosed embodiments. The method in FIG. 7 may be performed as part of a process to etch an underlying layer, which may or may not be a metal oxide layer. In operation 702 a substrate with a patterned EUV resist exposing a portion of an underlying layer is received in a process chamber. In some embodiments, features of the patterned EUV resist have an aspect ratio to the exposed portions of the underlying layer of between about 1 and about 5 or about 1 and about 2, e.g. about 1.5. The semiconductor substrate may be in the process chamber from a previous operation or may be introduced to the process chamber.

In operation 704 the patterned EUV resist is descummed in accordance with the process of FIGS. 3 and 10, as described above. In some embodiments a single ALE cycle according to FIG. 3 is performed. In other embodiments multiple ALE cycles are performed. In some embodiments operation 704 may not completely descum the patterned EUV resist. The extent to which operation 704 is performed may depend on whether any scum on the substrate impacts the critical dimension of the patterned EUV resist. In some embodiments the ALE process will also etch the underlying layer.

In operation 706 a precursor layer of silicon-containing precursor is deposited on the patterned EUV resist. The precursor is generally deposited “selectively” with respect with respect to the top of the features of the patterned EUV resist, such that more precursor deposits on top of the features than sidewalls or the exposed portions of the metal oxide layer. For example, in some embodiments there is no sidewall deposition of precursor. In some embodiments, the silicon-containing oxide precursor does not deposit on the underlying layer due to the higher aspect ratio. In embodiments where the aspect ratio is lower, silicon-containing precursor may also deposit on the underlying layer. Example process conditions for operation 706 are the same as for operation 108 for FIG. 1, above. In some embodiments the silicon-containing precursor is SiH₄, Si₂H₂, or SiCl₄.

In some embodiments an optional operation 708 is performed where the patterned EUV resist and the precursor layer are etched according to the process of FIG. 3. The ALE process may remove additional scum that was not removed in operation 704 above, as well as portions of the underlying layer and portions of the precursor layer. In some embodiments multiple ALE cycles are performed to remove scum or other non-desirable deposition on the underlying layer while the precursor layer protects the features of the EUV resist.

In some embodiments operation 706 and 708 are cycled to fill divots in the patterned EUV resist. In some embodiments more silicon-containing precursor will deposit within divots than areas surrounding the divots in operation 706, likely due to the divots having a greater surface area relative to the flatter surrounding field. In some embodiments, operation 708 will etch within divots less than the surrounding, thicker area. By cycling operations 706 and 708, any divots may be gradually filled by the silicon-containing precursor layer, reducing variability in the EUV resist thickness.

In operation 710 the precursor layer of silicon containing precursor is oxidized to form a silicon oxide cap. This is done by exposing the substrate to an oxidant, i.e. an oxygen-containing gas, while igniting a plasma, which reacts with the silicon-containing precursor to form a silicon oxide cap on the patterned EUV resist. The silicon oxide cap is selectively formed on top of the features of the patterned EUV resist, rather than the sidewalls, maintaining the sidewall profile of the features. Suitable oxidants and process conditions for operation 840 are the same as operation 112, above.

In operation 712 the underlying layer is etched, using the patterned EUV resist and the silicon oxide cap. The silicon oxide cap protects the patterned EUV resist from the etchant gas, preventing or inhibiting etching of the patterned EUV resist until the silicon oxide cap has been etched. In some embodiments the silicon oxide cap is completely removed during etching of the underlying layer, while in other embodiments the silicon oxide cap is not removed. Example process conditions for operation 712 may be the same as for operation 114 in FIG. 1, above. In some embodiments different etch chemistries may be used, so long as there is sufficient etch selectivity between the underlying layer and the combination of the patterned EUV resist and silicon oxide cap that the underlying layer can be etched using the combination as a mask. The particular etch chemistry to be used depends on the materials comprising the underlying layer.

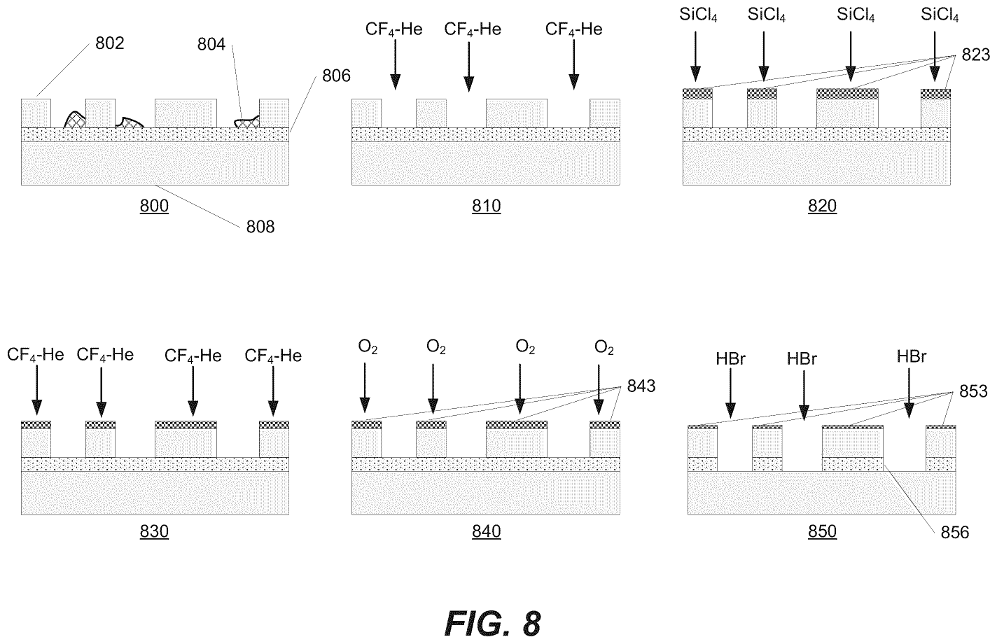

A particular example of the method of FIG. 7 is discussed below with reference to FIG. 8. FIG. 8 presents an example embodiment of a side view of a semiconductor substrate during capping of a patterned EUV resist during an etch process. At operation 800 a semiconductor substrate 808 having a metal oxide layer 806, carbon-containing scum 804, and patterned EUV resist features 802 is provided to a processing chamber.

At operation 810 the substrate is descummed by an ALE process using CF₄ to adsorb onto surfaces of the substrate, and He ions to sputter the adsorbed layer. Operation 810 may be repeated until scum 804 is sufficiently removed, performing multiple ALE cycles. The result of operation 810 is the removal of scum 804. In some embodiments operation 810 also etches the features 802 and the underlying layer 806. Operation 810 may be performed using the same process conditions as presented by FIG. 3, above.

In some embodiments, operation 810 is not performed. In some embodiments scum 804 may be insignificant enough such that a descum operation is unnecessary. In some embodiments the EUV lithography process may not create sufficient scum to impact the critical dimension of the patterned EUV resist. Generally, if the scum does not impact the critical dimension of the etch process, a descum operation may not be performed.

In operation 820 SiCl₄ is selectively deposited on top of features 802 to create a silicon-containing precursor layer 823. SiCl₄ does not deposit, or deposits less, on the underlying layer 806 due to the aspect ratio of the patterned EUV resist and the exposed portions of the underlying layer. SiCl₄ also does not deposit on the sidewalls of the features, depositing entirely or mostly on top of features 802.

In operation 830 the silicon-containing precursor layer is etched using an ALE process with CF₄ to adsorb onto surfaces of the silicon-containing precursor layer, and He ions to desorb the adsorbed layer. This may be done to remove a portion of the silicon-containing precursor layer. In some embodiments this may be advantageous to reduce the aspect ratio of the patterned EUV resist or maintain the critical dimension of features of the patterned EUV resist. In some embodiments SiCl₄ deposits on the exposed portions of the underlying layer during operation 820, and operation 830 removes this deposition.

In some embodiments operation 830 is not performed. In some embodiments the SiCl₄ does not sufficiently deposit on the exposed portions of the underlying layer to require an etch operation.

In some embodiments operation 820 and 830 are cycled to fill divots in the EUV resist. Operation 830 will etch areas with greater surface areas more than areas with less surface area, thereby etching within divots less than the surrounding area. By cycling operations 820 and 830, any divots may be gradually filled by the silicon-containing precursor layer 833, reducing variability in the EUV resist thickness.

In operation 840 the silicon-containing precursor layer 823 is oxidized to create a silicon oxide cap 843. This is done by exposing the substrate to an oxidant, i.e. an oxygen-containing gas, while igniting a plasma, which reacts with the silicon-containing precursor to form a silicon oxide cap on the patterned EUV resist. The silicon oxide cap is selectively formed on top of the features of the patterned EUV resist, rather than the sidewalls, maintaining the sidewall profile of the features.

Finally, in operation 850 the underlying layer is etched using an HBr plasma. As the exposed portions of the underlying layer 806 are etched by the HBr plasma, a patterned underlying layer 856 is formed. Patterned underlying layer 856 has the same patterning as features 802 of the patterned EUV resist. The silicon oxide cap 843 is also etched to a thinner cap 853, but etches at a lower rate than the underlying layer. In some embodiments the silicon oxide cap is completely removed during etching of the underlying layer, while in other embodiments the silicon oxide cap is not removed.

### Deposition Materials

Deposition of a precursor layer or cap may be a plasma deposition including a plasma-enhanced chemical vapor deposition (PECVD) process or a high-density plasma chemical vapor deposition (HDP-CVD) process according to various embodiments. In embodiments in which the etch process is performed in a capacitively-coupled plasma etching apparatus, a PECVD process may be advantageously performed, and in embodiments in which the etch process is performed in an inductively-coupled plasma etching apparatus, an HDP-CVD process may be advantageously performed.

In depositing a silicon-containing oxide precursor, any appropriate silicon-containing precursor may be used including silanes (e.g., SiH₄), polysilanes (H₃Si—(SiH₂)ₙ—SiH₃) where n≥1, organosilanes, halogenated silanes, and aminosilanes. Organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like, may be used. A halogenated silane contains at least one halogen group and may or may not contain hydrogens and/or carbon groups. Examples of halogenated silanes are iodosilanes, bromosilanes, chlorosilanes and fluorosilanes. Specific chlorosilanes are tetrachlorosilane (SiCl₄), trichlorosilane (HSiCl₃), dichlorosilane (H₂SiCl₂), monochlorosilane (ClSiH₃), chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like. An aminosilane includes at least one nitrogen atom bonded to a silicon atom, but may also contain hydrogens, oxygens, halogens and carbons. Examples of aminosilanes are mono-, di-, tri- and tetra-aminosilane (H₃Si(NH₂)₄, H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tertiarybutylamino) silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃ and the like.

The deposited films may be amorphous, with film composition depending on the particular precursor and co-reactants used, with organosilanes resulting a-SiC:H films and aminosilanes resulting in a-SiN:H or a-SiCN:H films.

In depositing carbon-based films, a hydrocarbon precursor of the formula CₓH_{y}, wherein X is an integer between 2 and 10, and Y is an integer between 2 and 24, may be used. Examples include methane (CH₄), acetylene (C₂H₂), ethylene (C₂H₄), propylene (C₃H₆), butane (C₄H₁₀), cyclohexane (C₆H₁₂), benzene (C₆H₆), and toluene (C₇H₈).

In some embodiments, the cap may be doped or include a material such as boron or phosphorous. Additional dopants include arsenic, sulfur and selenium. In this manner, etch selectivity to a mask or cap layer may be improved. For example, for doped dielectrics (particularly silicon dioxide-based dielectrics), the process gas may include a dopant precursor such as a boron-containing gas, a phosphorus-containing gas, a carbon-containing gas, or a mixture thereof. In a specific embodiment, the gas includes one or more boron-containing reactants and one or more phosphorus-containing reactants and the dielectric film includes a phosphorus- and boron-doped silicon oxide glass (BPSG). Examples of suitable boron and phosphorus precursor gases include borane (BH₃), diborane (B₂H₆), and triborane (B₃H₇) and phosphine (PH₃). Examples of arsenic-containing, sulfur-containing, and selenium-containing gases include hydrogen selenide (H₂Se), hydrogen arsenide (AsH₃), and hydrogen sulfide (H₂S).

If the cap is to contain an oxynitride (e.g., silicon oxynitride), then the deposition gas may include a nitrogen-containing reactant such as N₂, NH₃, NO, N₂O, and mixtures thereof. Examples of deposited films include boron-doped silicon, silicon boride, silicon boride carbon, and the like.

### Apparatus

FIG. 11 schematically shows a cross-sectional view of an inductively coupled plasma etching apparatus 1100 in accordance with certain embodiments herein. A Kiyo™ reactor, produced by Lam Research Corp. of Fremont, CA, is an example of a suitable reactor that may be used to implement the techniques described herein. The inductively coupled plasma etching apparatus 1100 includes an overall etching chamber structurally defined by chamber walls 1101 and a window 1111. The chamber walls 1101 may be fabricated from stainless steel or aluminum. The window 1111 may be fabricated from quartz or other dielectric material. An optional internal plasma grid 1150 divides the overall etching chamber into an upper sub-chamber 1102 and a lower sub-chamber 1103. In most embodiments, plasma grid 1150 may be removed, thereby utilizing a chamber space made of sub-chambers 1102 and 1103. A chuck 1117 is positioned within the lower sub-chamber 1103 near the bottom inner surface. The chuck 1117 is configured to receive and hold a semiconductor wafer 1119 upon which the etching process is performed. The chuck 1117 can be an electrostatic chuck for supporting the wafer 1119 when present. In some embodiments, an edge ring (not shown) surrounds chuck 1117, and has an upper surface that is approximately planar with a top surface of a wafer 1119, when present over chuck 1117. The chuck 1117 also includes electrostatic electrodes for chucking and dechucking the wafer. A filter and DC clamp power supply (not shown) may be provided for this purpose. Other control systems for lifting the wafer 1119 off the chuck 1117 can also be provided. The chuck 1117 can be electrically charged using an RF power supply 1123. The RF power supply 1123 is connected to matching circuitry 1121 through a connection 1127. The matching circuitry 1121 is connected to the chuck 1117 through a connection 1125. In this manner, the RF power supply 1123 is connected to the chuck 1117.

A coil 1133 is positioned above window 1111. The coil 1133 is fabricated from an electrically conductive material and includes at least one complete turn. The exemplary coil 1133 shown in FIG. 11 includes three turns. The cross-sections of coil 1133 are shown with symbols, and coils having an “X” extend rotationally into the page, while coils having a “.” extend rotationally out of the page. An RF power supply 1141 is configured to supply RF power to the coil 1133. In general, the RF power supply 1141 is connected to matching circuitry 1139 through a connection 1145. The matching circuitry 1139 is connected to the coil 1133 through a connection 1143. In this manner, the RF power supply 1141 is connected to the coil 1133. An optional Faraday shield 1149 is positioned between the coil 1133 and the window 1111. The Faraday shield 1149 is maintained in a spaced apart relationship relative to the coil 1133. The Faraday shield 1149 is disposed immediately above the window 1111. The coil 1133, the Faraday shield 1149, and the window 1111 are each configured to be substantially parallel to one another. The Faraday shield may prevent metal or other species from depositing on the dielectric window of the plasma chamber.

Process gases may be supplied through a main injection port 1160 positioned in the upper chamber and/or through a side injection port 1170, sometimes referred to as an STG. A vacuum pump, e.g., a one or two stage mechanical dry pump and/or turbomolecular pump 1140, may be used to draw process gases out of the process chamber 1124 and to maintain a pressure within the process chamber 1100 by using a closed-loop-controlled flow restriction device, such as a throttle valve (not shown) or a pendulum valve (not shown), during operational plasma processing.

During operation of the apparatus, one or more reactant gases may be supplied through injection ports 1160 and/or 1170. In certain embodiments, gas may be supplied only through the main injection port 1160, or only through the side injection port 1170. In some cases, the injection ports may be replaced by showerheads. The Faraday shield 1149 and/or optional grid 1150 may include internal channels and holes that allow delivery of process gases to the chamber. Either or both of Faraday shield 1149 and optional grid 1150 may serve as a showerhead for delivery of process gases.

Radio frequency power is supplied from the RF power supply 1141 to the coil 1133 to cause an RF current to flow through the coil 1133. The RF current flowing through the coil 1133 generates an electromagnetic field about the coil 1133. The electromagnetic field generates an inductive current within the upper sub-chamber 1102. During an etch process, the physical and chemical interactions of various generated ions and radicals with the wafer 1119 selectively etch features of the wafer.

If the plasma grid is used such that there is both an upper sub-chamber 1102 and a lower sub-chamber 1103, the inductive current acts on the gas present in the upper sub-chamber 1102 to generate an electron-ion plasma in the upper sub-chamber 1102. The optional internal plasma grid 1150 limits the amount of hot electrons in the lower sub-chamber 1103. In some embodiments, the apparatus is designed and operated such that the plasma present in the lower sub-chamber 1103 is an ion-ion plasma.

Both the upper electron-ion plasma and the lower ion-ion plasma may contain positive and negative ions, through the ion-ion plasma will have a greater ratio of negative ions to positive ions. Volatile etching byproducts may be removed from the lower-subchamber 1103 through port 1122.

The chuck 1117 disclosed herein may operate at elevated temperatures ranging between about 30° C. and about 250° C. The temperature will depend on the etching process operation and specific recipe. In some embodiments, the chamber 1101 may also operate at pressures in the range of between about 1 mTorr and about 95 mTorr. In certain embodiments, the pressure may be higher as disclosed above.

Chamber 1101 may be coupled to facilities (not shown) when installed in a clean room or a fabrication facility. Facilities include plumbing that provide processing gases, vacuum, temperature control, and environmental particle control. These facilities are coupled to chamber 1101, when installed in the target fabrication facility. Additionally, chamber 1101 may be coupled to a transfer chamber that allows robotics to transfer semiconductor wafers into and out of chamber 1101 using typical automation.

In some embodiments, a system controller 1130 (which may include one or more physical or logical controllers) controls some or all of the operations of an etching chamber. Controllers are described further below.

FIG. 12 is a schematic depiction of an example of a capacitively-coupled plasma etching apparatus according to various embodiments. A plasma etch chamber 1200 includes an upper electrode 1202 and a lower electrode 1204 between which a plasma may be generated. A substrate 1299 having a patterned EUV resist thereon and as described above may be positioned on the lower electrode 1204 and may be held in place by an electrostatic chuck (ESC). Other clamping mechanisms may also be employed. The plasma etch chamber 1200 may include plasma confinement rings 1206 that keep the plasma over the substrate and away from the chamber walls. Other plasma confinement structures, e.g. as a shroud that acts an inner wall, may be employed. In some embodiments, the plasma etch chamber may not include any such plasma confinement structures.

In the example of FIG. 12, the plasma etch chamber 1200 includes two RF sources with RF source 1210 connected to the upper electrode 1202 and RF source 1212 connected to the lower electrode 1204. Each of the RF sources 1210 and 1212 may include one or more sources of any appropriate frequency including 2 MHZ, 13.56 MHZ, 27 MHZ, and 60 MHz. Gas may be introduced to the chamber from one or more gas sources 1214, 1216, and 1218. For example, the gas source 1214 may include deposition or etching gases as described above. Gas may be introduced to the chamber through inlet 1220 with excess gas and reaction byproducts exhausted via exhaust pump 1222.

One example of a plasma etch chamber that may be employed is a 2300® Flex™ reactive ion etch tool available from Lam Research Corp. of Fremont, CA. Further description of plasma etch chambers may be found in U.S. Pat. Nos. 6,841,943 and 8,552,334, which are herein incorporated by reference for all purposes.

Returning to FIG. 12, a controller 1130 may be connected to the RF sources 1210 and 1212 as well as to valves associated with the gas sources 1214, 1216, and 1218, and to the exhaust pump 1222. In some embodiments, the controller 1130 controls all of the activities of the plasma etch chamber 1200.

The following discussion of a controller 1130 may be applied as appropriate to the controller 1130 in FIGS. 11 and 12. The controller 1130 may execute control software stored in mass storage device, loaded into a memory device, and executed on a processor. Alternatively, the control logic may be hard coded in the controller 1130. Alternatively, the control logic may be hard coded in the controller 1130. Applications Specific Integrated Circuits, Programmable Logic Devices (e.g., field-programmable gate arrays, or FPGAs) and the like may be used for these purposes. In the following discussion as well as in the discussion of the controller in FIG. 6, wherever “software” or “code” is used, functionally comparable hard coded logic may be used in its place.

The control software may include instructions for controlling the timing of application and/or magnitude of any one or more of the following chamber operational conditions: the mixture and/or composition of gases, chamber pressure, chamber temperature, wafer/wafer support temperature, the bias applied to the wafer, the frequency and power applied to coils or other plasma generation components, wafer position, wafer movement speed, and other parameters of a particular process performed by the tool. For example, the control software may include instructions to flow the reactants discussed above, such as silicon-containing precursors, halogen-containing gases, oxidants, or inert gases. Control software may be configured in any suitable way. For example, various process tool component subroutines or control objects may be written to control operations of the process tool components necessary to carry out various process tool processes. Control software may be coded in any suitable compute readable programming language.

In some embodiments, the control software may include input/output control (IOC) sequencing instructions for controlling the various parameters described above. Other computer software and/or programs stored on mass storage device and/or memory device associated with the controller 1130 may be employed in some embodiments. Examples of programs or sections of programs for this purpose include a process gas control program, a pressure control program, and RF source control programs.

A process gas control program may include code for controlling gas composition (e.g., deposition and treatment gases as described herein) and flow rates and optionally for flowing gas into a chamber prior to deposition to stabilize the pressure in the chamber. A pressure control program may include code for controlling the pressure in the chamber by regulating, for example, a throttle valve in the exhaust system of the chamber, a gas flow into the chamber, etc. A RF source control program may include code for setting RF power levels applied to the electrodes in accordance with the embodiments herein.

In some embodiments, there may be a user interface associated with the controller 1130. The user interface may include a display screen, graphical software displays of the apparatus and/or process conditions, and user input devices such as pointing devices, keyboards, touch screens, microphones, etc.

In some embodiments, parameters adjusted by controller 1130 may relate to process conditions. Non-limiting examples include process gas composition and flow rates, temperature, pressure, plasma conditions (such as RF bias power levels), pressure, temperature, etc. These parameters may be provided to the user in the form of a recipe, which may be entered utilizing the user interface. There parameters may be in a similar form as the process conditions provided herein.

Signals for monitoring the process may be provided by analog and/or digital input connections of system controller 1130 from various process tool sensors. The signals for controlling the process may be output on the analog and digital output connections of the plasma etch chamber. Non-limiting examples of sensors that may be monitored include mass flow controllers, pressure sensors (such as manometers), thermocouples, etc. Appropriately programmed feedback and control algorithms may be used with data from these sensors to maintain process conditions.

The controller 1130 may provide program instructions for implementing the above-described directional deposition processes as well as subsequent etch processes. The program instructions may control a variety of process parameters, such as RF bias power level, pressure, temperature, etc. The instructions may control the parameters to directionally deposit cap-build up films according to various embodiments described herein. For example, the instructions may control the flow rate of silicon-containing oxide precursors, or the power of halogen-containing plasma.

A controller 1130 will typically include one or more memory devices and one or more processors configured to execute the instructions so that the apparatus will perform a method in accordance with disclosed embodiments. Machine-readable media including instructions for controlling process operations in accordance with disclosed embodiments may be coupled to the controller 1130, for example as describe above.

In some implementations, the controller 1130 may be or form part of a system controller that is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller, in some implementations, may be a part of or coupled to a computer that is integrated with, coupled to the system, otherwise networked to the system, or a combination thereof. For example, the system controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller receives instructions in the form of data, which specify parameters for each of the processing steps to be performed during one or more operations. It should be understood that the parameters may be specific to the type of process to be performed and the type of tool that the system controller is configured to interface with or control. Thus as described above, the system controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

In some embodiments, the PECVD deposition may employ a remote, radical-assisted plasma or a microwave plasma. Such a deposition may be performed in an etch chamber configured with a remote or microwave plasma generator or may be performed in a deposition chamber connected under vacuum to an etch chamber. Similarly, in some embodiments, a treatment operation may be performed using a remote radical-assisted plasma or a microwave plasma.

Example process parameters are given as follows. Example pressure ranges are from 5 mT to 1000 mT, and in some embodiments, between 40 mT to 100 mT. In a treatment operation, example pressures may range from 5 mT to 300 mT.

Example plasma powers for an inductively coupled plasma source (e.g., a transformer coupled plasma (TCP) source available from Lam Research, Fremont California is 10 W to 1200 W, 20 W to 500 W, or 50 W to 300 W. Example plasma powers for a deposition operation range from 20 W to 200 W. Example plasma powers for a treatment operation range from 20 W to 1200 W.

Example bias voltages range from 0 V to −500 V, 0 to −80 V, for example −50 V. Bias voltage may also be expressed in terms of magnitude, e.g., 0 to 500 V, 0 to 80 V, or 0 to 50 V. Example flow rates at the deposition step range from 1 sccm to 2000 sccm, from 1 to 300 sccm, or 100 sccm. Example flow rates at the treatment step range from 1 to 2000 sccm, 1 to 500 sccm, or 300 sccm. Example substrate temperatures range from 40° C. to 250° or 60° C. to 120° C. Deposition and treatment exposure time may range from 0.5 s to 20 s in some embodiments, or from 3 s to 10 s, or 4 s to 6 s, with an example of a process time for the multi-cycle process. In some examples, between 10 and 100 cycles are performed.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. (canceled)

2. A method, comprising:
providing to a processing chamber a semiconductor substrate comprising a patterned EUV resist exposing a portion of an underlying metal oxide layer, wherein the substrate comprises scum on the patterned EUV resist, the exposed portion of the underlying metal oxide layer, or both; and
performing one or more cycles of:
exposing the patterned EUV resist to a reactant to modify the scum; and
exposing the modified scum to a plasma of an inert gas to remove the modified scum.

3. The method of claim 2, wherein the reactant is a halogen-containing gas.

4. The method of claim 3, wherein the halogen-containing gas comprises one or more of a halogen gas and a halide gas.

5. The method of claim 4, wherein the halogen gas comprises Br₂, Cl₂, F₂, I₂, or any combinations thereof.

6. The method of claim 4, wherein the halide gas comprises fluorocarbons,
hydrofluorocarbons, organochlorides, organobromides, organoiodides (CₓI_{y}), HBr, HCl, HF, HI, or any combinations thereof.

7. The method of claim 2, wherein the reactant is an oxygen-containing gas.

8. The method of claim 2, wherein the inert gas comprises helium, neon, argon, xenon, or any combinations thereof.

9. The method of claim 2, wherein exposing the modified scum to a plasma is performed at a voltage bias between 0V and 100V in a continuous mode or 100V to 400V in a pulsing mode, inclusive.

10. The method of claim 2, wherein exposing the modified scum to a plasma is performed at a power per substrate between about 50 W and about 150 W.

11. A method, comprising:
providing to a processing chamber a semiconductor substrate comprising a patterned EUV resist exposing a portion of an underlying metal oxide layer, wherein the patterned EUV resist has one or more divots; and
filling the one or more divots by performing one or more cycles of:
selectively depositing material on the patterned EUV resist; and
selectively etching the patterned EUV resist, wherein etching inside divots occurs at a lower rate than non-divot areas.

12. The method of claim 11, wherein the material substantially does not deposit on the exposed portion of the underlying metal oxide layer.

13. The method of claim 11, wherein the material is a silicon-containing material.

14. The method of claim 13, wherein selectively depositing material on the patterned EUV resist comprises:
treating the exposed portion of the metal oxide layer with a halogen-containing plasma; and
selectively depositing a silicon-containing precursor on the patterned EUV resist.

15. The method of claim 13, further comprising exposing the semiconductor substrate to an oxygen-containing reactant to convert the silicon-containing material to silicon oxide.

16. The method of claim 15, wherein the oxygen-containing reactant is chosen from the group of H₂O, NO, N₂O, CO₂, O₂, or O₃.

17. The method of claim 11, wherein the material is a carbon-containing material.

18. The method of claim 17, wherein selectively depositing material on the patterned EUV resist comprises:
exposing the semiconductor substrate to a gas mixture comprising hydrocarbon, hydrogen, and inert gas in the presence of a plasma.

19. The method of claim 18, wherein material does not deposit on the portion of the underlying metal oxide layer.

20. The method of claim 18, wherein the hydrocarbon is one or more precursors of the formula CₓH_{y}, wherein X is an integer between 2 and 10 and Y is an integer between 2 and 24.

21. The method of claim 18, wherein the inert gas comprises helium, neon, argon, or xenon.

22. The method of claim 11, wherein selectively etching the patterned EUV resist comprises:
exposing the semiconductor substrate to a reactant that modifies the deposited material; and
exposing the modified material to a plasma of an inert gas.
